(19) United States
(12) Patent Application Publication
(10) Pub. No.: US 2008/0180919 A1
(43) Pub. Date: Jul. 31, 2008

(54) Semiconductor module, module substrate structure, and method of fabricating the same

(75) Inventor: Gwang-Man Lim, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/785,477

(22) Filed: Apr. 18, 2007

(30) Foreign Application Priority Data
Jan. 29, 2007 (KR) 10-2007-009000

(51) Int. Cl. H05K 7/02; H01L 21/56

(52) U.S. Cl. 361/728; 438/115; 257/E21.502

(57) ABSTRACT

A module substrate structure may include a substrate, a passive device mounted on the substrate, and a protection layer covering the passive device. The protection layer may cover the passive device either completely or partly. Where a plurality of passive devices are present, the protection layer may cover either all or a selected number of the passive devices. A semiconductor module may include the module substrate structure in addition to a semiconductor chip mounted on the substrate, and an encapsulant covering the substrate. The semiconductor chip may be electrically connected to the passive device. Manufacturing processes (e.g., plasma treatment) may cause the passive device to be bombarded by ions and become electrically charged. Consequently, the electrical charges built up in the passive device may discharge (flow) and cause damage to the semiconductor chip. Accordingly, a protection layer covering the passive device may reduce (if not prevent) the possibility of damage to the semiconductor chip during manufacturing processes that may cause the passive device to become electrically charged.

### PRIORITY STATEMENT

This U.S. non-provisional patent application claims priority under 35 U.S.C. §119(a) to Korean Patent Application No. 10-2007-0009000, filed on Jan. 29, 2007 in the Korean Intellectual Property Office (KIPO), the entire contents of which are incorporated herein by reference.

### BACKGROUND

1. Technical Field

Example embodiments relate to a semiconductor device and a method of fabricating the same. Example embodiments also relate to a semiconductor module, a module substrate structure for the semiconductor module, and a method of fabricating the same.

2. Description of the Related Art

A semiconductor module (e.g., memory card, multimedia card, central processing unit, multi-chip package) may include a semiconductor chip mounted on a module substrate structure with one or more passive devices mounted on the module substrate structure as interfaces for the semiconductor chip and application devices. Prior to mounting or electrically connecting the semiconductor chip, it may be desirable to clean the surface of the module substrate structure or the semiconductor chip with a suitable cleaning process. For example, cleaning may be performed with a plasma treatment.

FIGS. 1 and 2 are views of a conventional semiconductor module. Referring to FIG. 1, the semiconductor module may include a semiconductor chip 12 and a passive device 14, mounted on a substrate 10. The passive device 14 may input/output a signal from/to the semiconductor chip 12 and reduce noise. One or more semiconductor chips 12 and passive devices 14 may be mounted on the substrate 10.

An interconnection 22 may be provided on the substrate 10 with a pad 16. The passive device 14 may directly contact the interconnection 22, and the pad 16 may be electrically connected to a pad 18 of the semiconductor chip 12. The pad 16 of the interconnection 22 and the pad 18 of the semiconductor chip 12 may be connected by a bonding wire 20.

The semiconductor chip 12 may be mounted on the substrate 10 with a tape or a high polymer resin. Referring to FIG. 2, a plasma treatment 30 may be used to remove impurities from the surface of the substrate 10 to improve adhesiveness between the substrate 10 and the semiconductor chip 12. Additionally, pad 16 and pad 18 may be cleaned with the plasma treatment 30. However, when performing a plasma treatment, plasma ions may bombard the passive device 14 (e.g., capacitor) and electrically charge it. For example, because a capacitor may have a relatively high dielectric constant, it may store a relatively large amount of electrical charges Qp. As a result, the electrical charges Qp stored in the capacitor may discharge (flow) into the semiconductor chip 12 when pad 16 is connected to pad 18. Consequently, the semiconductor chip 12 may be subjected to an electro-over-stress (EOS) surge Ie, which may damage circuits of the semiconductor chip 12.

### SUMMARY OF EXAMPLE EMBODIMENTS

Example embodiments may provide a module substrate structure and a semiconductor module including the module substrate structure as well as methods of fabricating the same.

A module substrate structure may include a substrate, at least one passive device mounted on the substrate, and a protection layer covering the passive device. A semiconductor chip region may be defined on the substrate, and the passive device may be a capacitor. The protection layer may cover the passive device partly or completely. Where the module substrate structure includes a plurality of passive devices, the protection layer may cover all or a selected number of the passive devices. A semiconductor module may include the module substrate structure described above, at least one semiconductor chip mounted on the substrate, and an encapsulant covering the passive device and/or semiconductor chip mounted on the substrate. The semiconductor chip may be mounted in the semiconductor chip region defined on the substrate and electrically connected to the passive device. Furthermore, a plurality of semiconductor chips may be mounted on the substrate by stacking the semiconductor chips or arranging them in rows and/or columns.

A method of fabricating a module substrate structure may include mounting at least one passive device on a substrate and forming a protection layer to cover the passive device. Forming the protection layer may involve a high molecular resin and the optional use of a mold. A method of fabricating a semiconductor module may include fabricating the module substrate structure described above, mounting at least one semiconductor chip on the substrate, and covering the passive device and/or semiconductor chip on the substrate with an encapsulant. Additionally, a plasma treatment may be used to clean the substrate surface and/or semiconductor chip surface prior to covering the passive device, semiconductor chip, and/or substrate with an encapsulant.

### BRIEF DESCRIPTION OF THE DRAWINGS

The accompanying drawings have been included to provide a further understanding of example embodiments. The drawings merely illustrate example embodiments and should not be interpreted as limiting the specification. Those ordinarily skilled in the art will appreciate the full scope of example embodiments when viewing the drawings together with the teachings as a whole.

FIGS. 1 and 2 are views of a conventional semiconductor module.

FIGS. 3 through 7 are views of a semiconductor module according to example embodiments.

FIG. 8 is a view of a module substrate structure according to example embodiments.

FIGS. 9 through 14 illustrate a method of fabricating a module substrate structure and a semiconductor module according to example embodiments.

FIGS. 15 and 16 illustrate a method of fabricating a semiconductor module according to example embodiments.

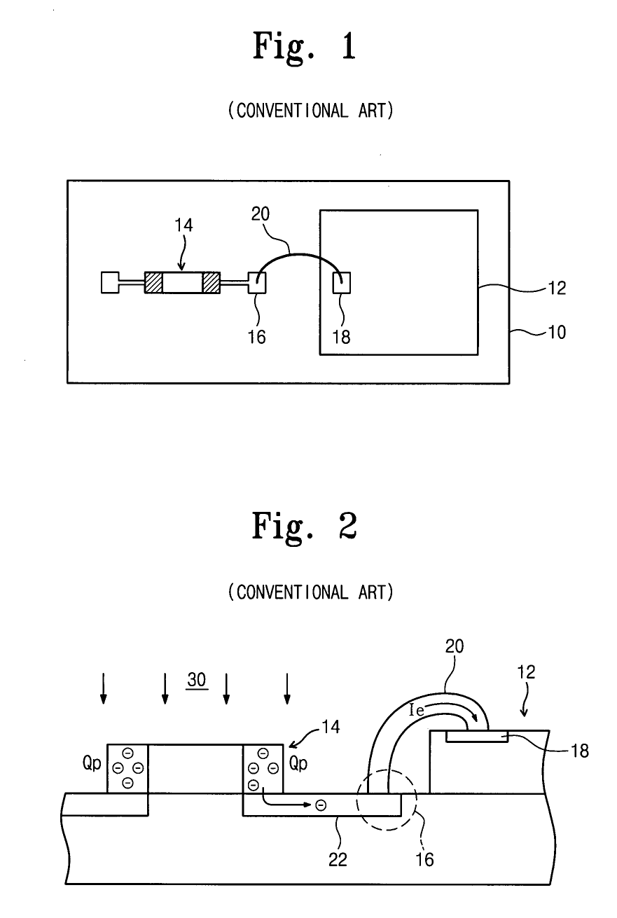

### DETAILED DESCRIPTION OF EXAMPLE EMBODIMENTS

Example embodiments will be described below in more detail with reference to the accompanying drawings. Example embodiments may, however, be embodied in different forms and should not be constructed as limited to the ones set forth herein. Rather, these example embodiments have been provided so that this disclosure will be thorough and fully convey the scope of the disclosure to those skilled in the art. In the figures, the dimensions of the layers and regions may have been exaggerated for purposes of illustration.

It will be understood that when an element or layer is referred to as being “on”, “connected to”, “coupled to”, or “covering” another element or layer, it can be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

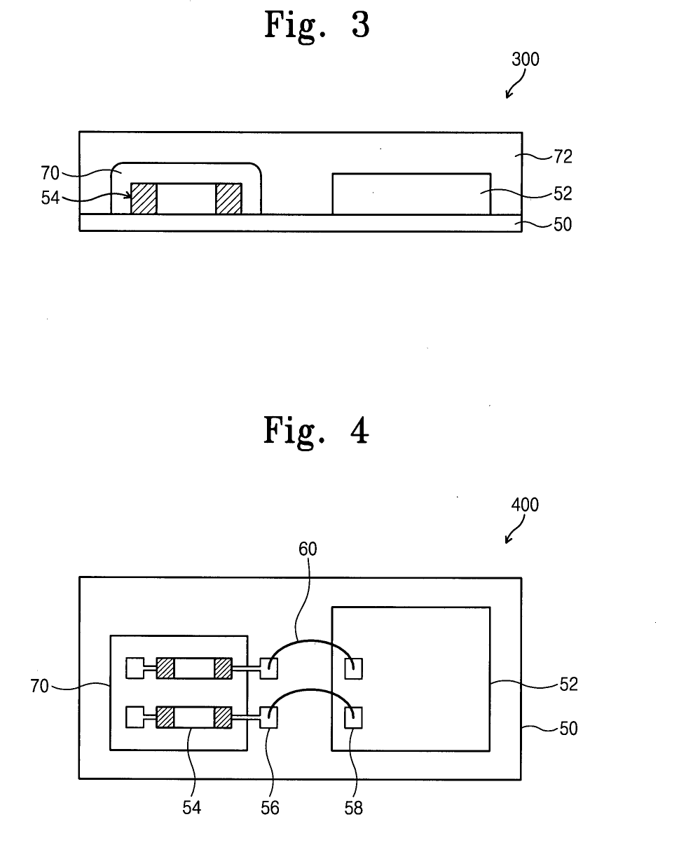

FIGS. 3 through 7 are views of a semiconductor module according to example embodiments. FIG. 3 is a sectional view of a semiconductor module according to example embodiments. Referring to FIG. 3, a semiconductor module 300 may include a substrate 50, a passive device 54, and/or a semiconductor chip 52 on the substrate 50. A protection layer 70 may cover the passive device 54, and an encapsulant 72 may cover the passive device 54 and/or semiconductor chip 52 on the substrate 50. As illustrated in FIG. 3, the encapsulant 72 may completely cover the substrate 50. Alternatively, the encapsulant 72 may cover only a portion of the substrate 50. A high polymer resin may be used for the encapsulant 72, and a metal cap may be used for the substrate 50.

FIG. 4 is a plan view of a semiconductor module according to example embodiments. Referring to FIG. 4, a semiconductor module 400 may include a plurality of passive devices 54 and a semiconductor chip 52. Interconnections, including a pad 56 and a bonding pad 58, may be formed on the substrate 50. The pad 56 of the passive device 54 may be electrically connected to the bonding pad 58 of the semiconductor chip by a bonding wire 60. The protection layer 70 may completely cover one or more of the passive devices 54, although the protection layer 70 may also just cover a portion of one or more of the passive devices 54. As illustrated in FIG. 4, a portion of the interconnections, including pad 56, may remain uncovered by the protection layer 70. Alternatively, the protection layer 70 may completely cover the interconnections, including pad 56, along with the passive devices 54. Furthermore, the semiconductor module 400 may alternatively include just one passive device 54 and a plurality of semiconductor chips 52.

Covering the passive devices 54 with the protection layer 70 may protect them from bombardment by ions during certain manufacturing processes, which may cause the passive devices 54 to become electrically charged (electrified). For example, where the passive devices 54 (e.g., capacitors) are electrically connected to the semiconductor chip 52 and bombarded by ions (e.g., plasma treatment), the resulting electrical charges built up in the passive devices 54 may discharge (flow) into and damage the semiconductor chip 52. Accordingly, the protection layer 70 may act as an electrification protection or prevention layer.

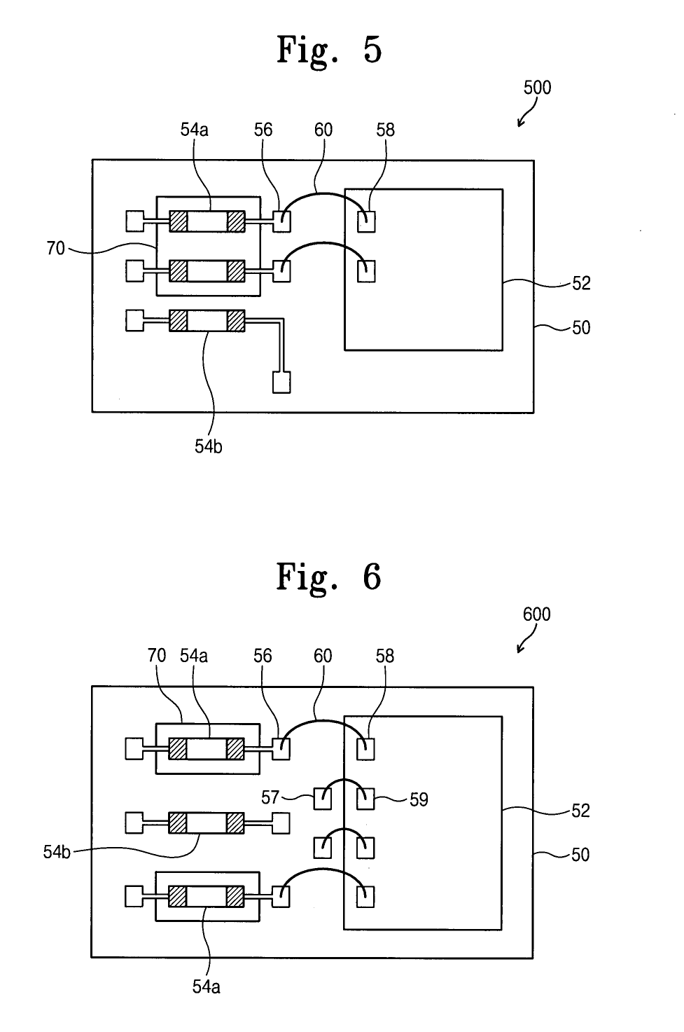

FIG. 5 is a plan view of a semiconductor module according to example embodiments. Referring to FIG. 5, a semiconductor module 500 may include one or more passive devices 54a and 54b on a substrate 50. The protection layer 70 may selectively cover the passive devices 54a electrically connected to the semiconductor chip 52, while the passive device 54b not connected to the semiconductor chip 52 remains uncovered. Additionally, the passive devices 54a may be grouped together in a desired region of the substrate 50, such that a single protection layer 70 may cover the passive devices 54a.

FIG. 6 is a plan view of a semiconductor module according to example embodiments. Referring to FIG. 6, the semiconductor module 600 may include a semiconductor chip 52 and one or more passive devices 54a and 54b, mounted on a substrate 50. The protection layer 70 may be formed on the passive devices 54a electrically connected to the semiconductor chip 52 and not formed on the other unconnected passive device 54b. Because the passive devices 54a have not been grouped together in FIG. 6, a plurality of protection layers 70 may be used to individually cover the passive devices 54a.

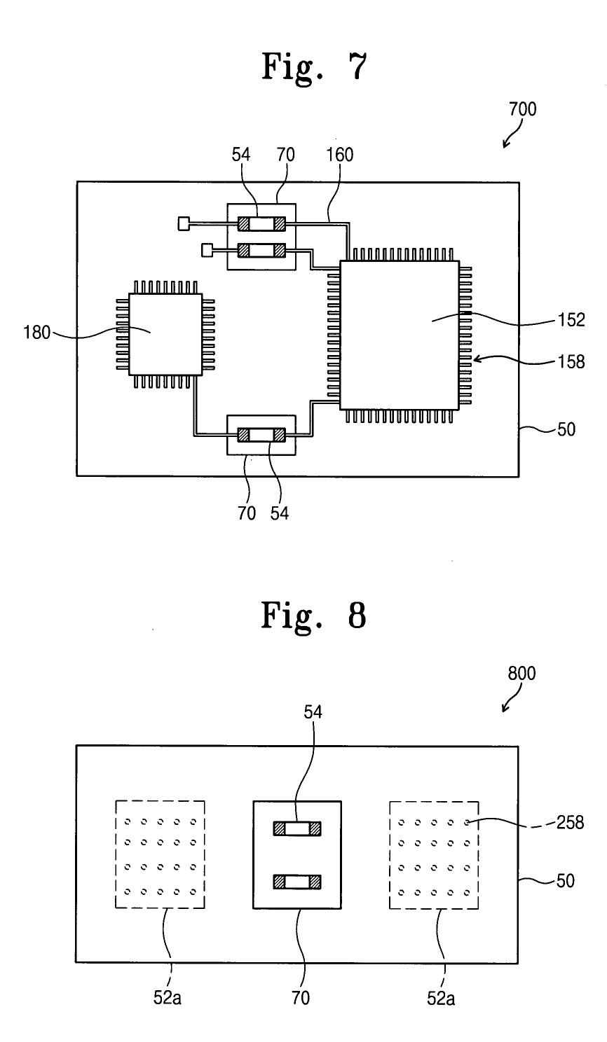

FIG. 7 is a plan view of a semiconductor module according to example embodiments. Referring to FIG. 7, a semiconductor module 700 may include a plurality of semiconductor chips 152 and 180 and passive devices 54, which may be mounted on a substrate 50. For example, a semiconductor chip 152 may be a memory chip, and semiconductor chip 180 may be a controller chip. The passive devices 54 may be connected to leads 158 of the semiconductor chips 152 and 180 by interconnections 160. Additionally, the passive devices 54 may be covered by the protection layer 70.

FIG. 8 is a plan view of a module substrate structure according to example embodiments. Referring to FIG. 8, the module substrate structure 800 for a semiconductor module may include a substrate 50, one or more passive devices 54, and/or one or more semiconductor chip regions 52a defined on the substrate 50. A protection layer 70 may cover the passive devices 54. Although not illustrated, the substrate 50 may include interconnections (e.g. multilayer wiring pattern) electrically connecting the passive devices 54. Also, terminals 258 may be arranged on the semiconductor chip regions 52a to electrically connect the semiconductor chip to the interconnections (not shown).

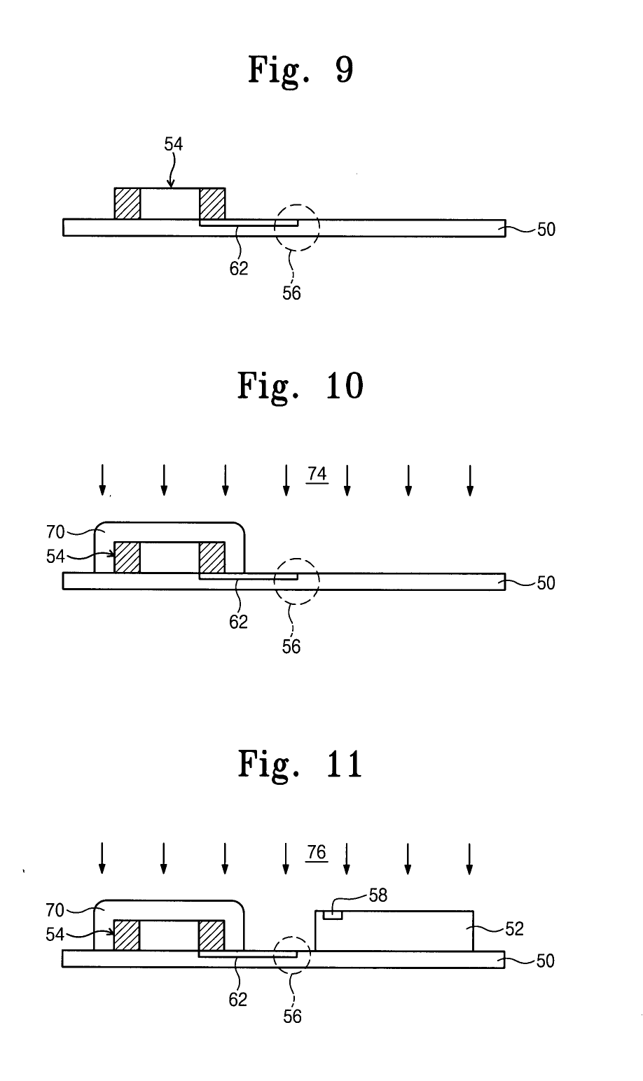

FIGS. 9 through 12 illustrate a method of fabricating a module substrate structure and a semiconductor module according to example embodiments. Referring to FIG. 9, one or more passive devices 54 may be mounted on a substrate 50. The substrate 50 may include one or more interconnections 62 (e.g., wiring) connected to the passive devices 54. Referring to FIG. 10, a protection layer 70 may be formed to cover the passive device 54. The protection layer 70 may be made of a high molecular compound or resin. For example, the protection layer 70 may be made by applying and solidifying a fluid epoxy resin or by molding and solidifying an epoxy molding compound (EMC). After forming the protection layer 70, a plasma treatment 74 may be optionally performed to clean the surface of the substrate 50. For example, cleaning the semiconductor chip region (not shown) may improve adhesion between a mounted semiconductor chip (not shown) and the substrate 50.

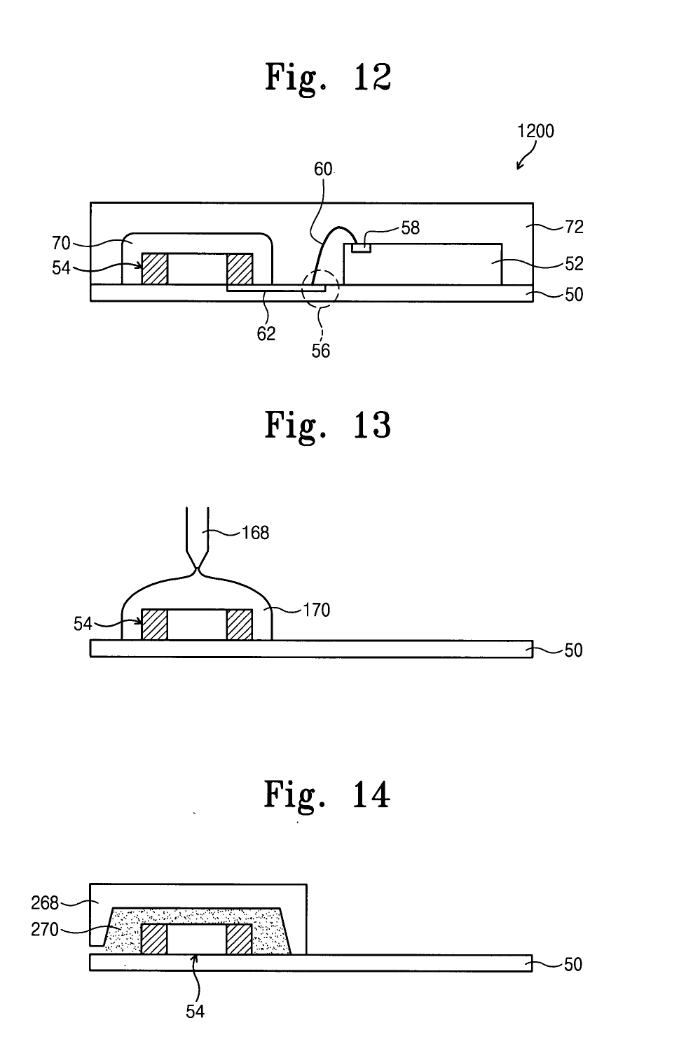

Referring to FIG. 11, a semiconductor chip 52 may be mounted on the substrate 50 using a resin or a tape (not shown). The semiconductor chip 52 may be electrically connected by bonding pad 58. Alternatively, the semiconductor chip 52 may be electrically connected by terminals 258 (e.g., FIG. 8) formed on the substrate 50. Prior to electrically connecting the semiconductor chip 52, a second plasma treatment process 76 may be performed on the surface of the semiconductor chip 52 and the surface of the substrate 50 to improve adhesion of the bonding wire 60 (e.g., FIG. 12) to pad 56 and bonding pad 58.

Referring to FIG. 12, pad 56 may be electrically connected to bonding pad 58 with a bonding wire 60. Alternatively, when the semiconductor chip 52 is electrically connected by the terminals 258 (e.g., FIG. 8) on the substrate, the bonding wire 60 may be unnecessary. Furthermore, an encapsulant 72 may cover the passive device 54 and semiconductor chip 52 on the substrate 50 to form a semiconductor module 1200. Alternatively, the encapsulant 72 may just cover a portion of the passive device 54 and/or semiconductor chip 52.

FIGS. 13 and 14 illustrate a method of fabricating a protection layer according to example embodiments. Referring to FIG. 13, the protection layer 70 (e.g., FIG. 3) may be formed by applying a fluid, high molecular compound/resin 170 on the passive device 54 and solidifying the high molecular compound/resin 170. As illustrated, a high molecular compound/resin 170 (e.g., an epoxy resin) may be applied to the passive device 54 by a dispenser 168. The resulting protection layer 70 (e.g., FIG. 3) may be achieved by solidifying the high molecular compound/resin 170 at room temperature or by performing a heat treatment.

Referring to FIG. 14, the protection layer 70 (e.g., FIG. 3) may be formed by EMC molding and solidification. As illustrated, a mold 268 may cover the passive device 54 so as to form a space between the passive device 54 and the mold 268. An EMC (epoxy molding compound) 270 may be injected into the space to cover the passive device 54. For example, the EMC 270 may be melted and injected within the mold 268 and hardened by a heat treatment to form the protection layer 70 (e.g., FIG. 3).

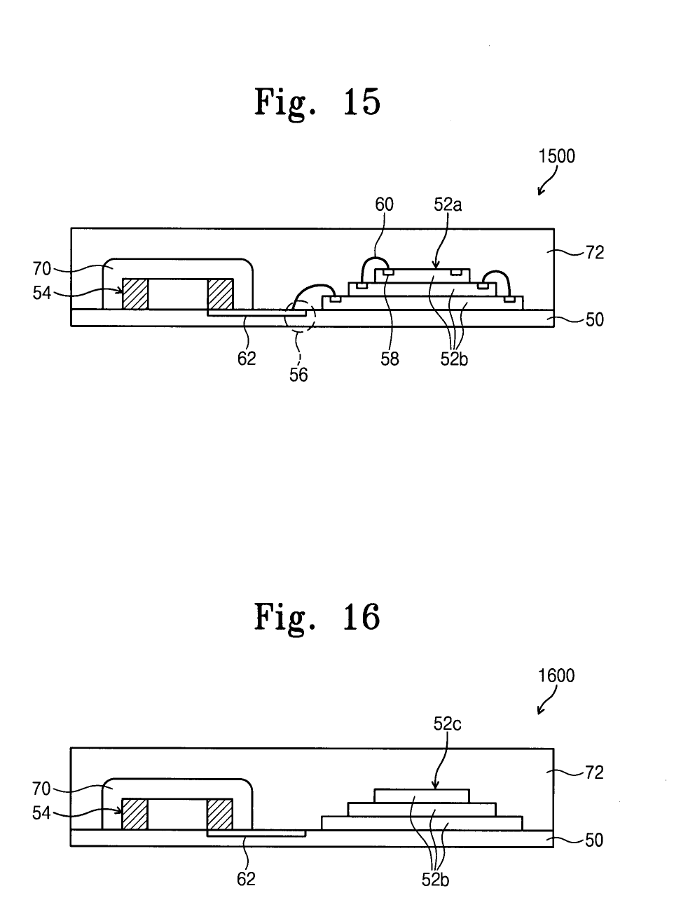

FIGS. 15 and 16 illustrate a method of fabricating a semiconductor module according to example embodiments. Referring to FIG. 15, the semiconductor module 1500 may include a plurality of semiconductor chips 52b. The plurality of semiconductor chips 52b may be stacked on the substrate 50 to form a semiconductor chip stack 52c. The semiconductor chips 52b may be electrically connected to each other through bonding pads 58 with bonding wire 60. A bonding wire 60 may electrically connect a bonding pad 58 of the lowest semiconductor chip 52b in the semiconductor chip stack 52c to a pad 56 on the substrate 50.

Referring to the semiconductor module 1600 in FIG. 16, the lowest semiconductor chip 52b in the semiconductor chip stack 52c may directly contact an interconnection (e.g., wiring layer) 62 on the substrate 50 for an electrical connection. For example, terminals 258 (e.g., FIG. 8) on the substrate 50 may directly contact the bonding pads 58 (not shown) of the semiconductor chip 52b for an electrical connection. The bonding pads 58 (not shown) of each semiconductor chip 52b may directly contact an adjacent semiconductor chip 52b in the semiconductor chip stack 52c so as to electrically connect all the semiconductor chips 52b in the semiconductor chip stack 52c.

Example embodiments should be considered merely illustrative and not interpreted as being restrictive. Those ordinarily skilled in the art will appreciate all the possible modifications, enhancements, embodiments, and equivalents that may be consistent within the spirit and scope of the teachings herein.

What is claimed is:

1. A module substrate structure comprising:
a substrate;
at least one passive device mounted on the substrate; and
a protection layer covering at least a portion of the at least one passive device.

2. The module substrate structure of claim 1, wherein the substrate includes a semiconductor chip region.

3. The module substrate structure of claim 1, wherein the at least one passive device is a capacitor.

4. The module substrate structure of claim 1, wherein the protection layer completely covers the at least one passive device.

5. The module substrate structure of claim 1, wherein the at least one passive device is in a passive device region of the substrate, and the protection layer covers the passive device region.

6. A semiconductor module, comprising:
the module substrate structure of claim 1;
at least one semiconductor chip mounted on the substrate; and
an encapsulant covering the at least one passive device and the at least one semiconductor chip.

7. The semiconductor module of claim 6, further comprising an interconnection on the substrate, the interconnection electrically connecting the at least one passive device and the at least one semiconductor chip.

8. The semiconductor module of claim 7, wherein the at least one semiconductor chip includes a bonding pad directly contacting the interconnection.

9. The semiconductor module of claim 7, wherein the at least one semiconductor chip includes a bonding pad connected to the interconnection by a bonding wire.

10. The semiconductor module of claim 6, wherein the at least one semiconductor chip includes a plurality of semiconductor chips, each having one or more bonding pads, wherein the plurality of semiconductor chips are stacked on the substrate;
the stacked plurality of semiconductor chips are connected to each other through the one or more bonding pads by a plurality of bonding wires; and
at least one of the stacked plurality of semiconductor chips is connected to an interconnection on the substrate by one or more bonding wires.

11. The semiconductor module of claim 6, wherein the at least one semiconductor chip includes a plurality of semiconductor chips, each having one or more bonding pads, wherein the plurality of semiconductor chips are stacked on the substrate;
the stacked plurality of semiconductor chips are connected to each other by one or more bonding pads of at least one of a plurality of semiconductor chips directly contacting an adjacent semiconductor chip; and
one or more bonding pads of at least one of the stacked plurality of semiconductor chips directly contacts an interconnection on the substrate.

12. The semiconductor module of claim 6, wherein the at least one passive device includes a plurality of passive devices mounted on the substrate, wherein one or more of the plurality of passive devices are electrically connected to the at least one semiconductor chip, and the protection layer covers the one or more of the plurality of passive devices electrically connected to the at least one semiconductor chip.

13. A method of fabricating a module substrate structure comprising;
mounting at least one passive device on a substrate; and
forming a protection layer to cover the at least one passive device.

14. The method of claim 13, wherein forming the protection layer comprises:
applying a high molecular resin to the passive device; and
solidifying the high molecular resin.

15. The method of claim 13, wherein forming the protection layer comprises:
covering the at least one passive device with a mold to form a space between the at least one passive device and the mold;
injecting a high molecular resin into the space; and
solidifying the high molecular resin.

16. The method of claim 13, further comprising performing a plasma treatment to clean a semiconductor chip region on the substrate.

17. The method of fabricating a semiconductor module, comprising:
fabricating a module substrate structure according to claim 13;
mounting at least one semiconductor chip on the substrate; and
covering the at least one passive device and the at least one semiconductor chip with an encapsulant.

18. The method of claim 17, wherein the at least one semiconductor chip is mounted on the substrate after forming the protection layer.

19. The method of claim 17, wherein the at least one semiconductor chip is mounted in a semiconductor chip region on the substrate.

20. The method of claim 17, further comprising performing a plasma treatment to clean the surface of the at least one mounted semiconductor chip prior to covering the at least one mounted passive device and the at least one mounted semiconductor chip with the encapsulant.
